(19) United States
(12) Patent Application Publication
(10) Pub. No.: US 2024/0428856 A1
(43) Pub. Date: Dec. 26, 2024

(54) SEMICONDUCTOR MEMORY DEVICE AND METHOD OF MANUFACTURING THE SAME

(71) Applicant: Kioxia Corporation, Tokyo (JP)

(72) Inventors: Akira TAKASHIMA, Fuchu (JP); Tsunehiro INO, Fujisawa (JP)

(73) Assignee: Kioxia Corporation, Tokyo (JP)

(21) Appl. No.: 18/669,736

(22) Filed: May 21, 2024

(30) Foreign Application Priority Data
Jun. 20, 2023 (JP) 2023-100615

(51) Int. Cl. G11C 16/04; H10B 43/27; H10B 43/35

(52) U.S. Cl. CPC G11C 16/0483; H10B 43/27; H10B 43/35

(57) ABSTRACT

A semiconductor memory device of an embodiment includes a stacked body including a first insulating layer, a first conductive layer and a second insulating layer; a semiconductor film extending in a first direction; a tunnel insulating film provided between the stacked body and the semiconductor film, the tunnel insulating film extending in the first direction; a first block insulating film provided between the first conductive layer and the tunnel insulating film; and a first charge storage film containing a metal oxide or a metal oxynitride and including: a first portion provided between the tunnel insulating film and the first block insulating film, a second portion provided between the tunnel insulating film and the first insulating layer, the second portion being connected to the first portion and a third portion provided between the tunnel insulating film and the second insulating layer, the third portion being connected to the first portion.

### CROSS-REFERENCE TO RELATED APPLICATION

This application is based upon and claims the benefit of priority from Japanese Patent Application No.2023-100615, filed on Jun. 20, 2023, the entire contents of which are incorporated herein by reference.

### FIELD

Embodiments described herein relate generally to semiconductor memory device and method of manufacturing the same.

### BACKGROUND

Large-capacity nonvolatile memories have been developed. This large-capacity nonvolatile memory is capable of low-voltage and low-current operation, high-speed switching, and miniaturization and high integration of memory cells.

Many metallic wires called bit lines and word lines are arranged in a memory cell array of the large-capacity nonvolatile memory. A voltage is applied to the memory cell connected to the bit line and the word line, and data is written to one memory cell corresponding to the bit line and the word line. The semiconductor memory device has been proposed in which memory cells are three-dimensionally arranged with stacked films in which a conductive layer serving as the word line and an insulating layer are alternately stacked.

### BRIEF DESCRIPTION OF THE DRAWINGS

FIG. 1 is a block diagram of the semiconductor memory device according to a first embodiment.

FIG. 2 is an equivalent circuit diagram of the memory cell array of the semiconductor memory device of the first embodiment.

FIG. 3 is schematic cross-sectional view of the main part of the semiconductor memory device of the first embodiment.

FIG. 4 is a schematic cross-sectional view showing a process for manufacturing the semiconductor memory device of the first embodiment.

FIG. 5 is a schematic cross-sectional view showing the process for manufacturing the semiconductor memory device of the first embodiment.

FIG. 6 is a schematic cross-sectional view showing the process for manufacturing the semiconductor memory device of the first embodiment.

FIG. 7 is a schematic cross-sectional view showing the process for manufacturing the semiconductor memory device of the first embodiment.

FIG. 8 is a schematic cross-sectional view showing the process for manufacturing the semiconductor memory device of the first embodiment.

FIG. 9 is a schematic cross-sectional view showing the process for manufacturing the semiconductor memory device of the first embodiment.

FIG. 10A-B are schematic cross-sectional views of the main part of the semiconductor memory device of a second embodiment.

FIG. 11 is a schematic cross-sectional view showing a process for manufacturing the semiconductor memory device of the second embodiment.

### DETAILED DESCRIPTION

Hereinafter, embodiments will be described with reference to the diagrams. In addition, in the diagrams, the same or similar elements are denoted by the same or similar reference numerals.

In the present specification, to show the positional relationship of the components and the like, the upward direction of the drawings is described as “up”, and the downward direction of the drawings is described as “down”. In the present specification, the terms “up” and “down” do not necessarily indicate the relationship with the direction of gravity.

For example, Secondary Ion Mass Spectrometry: SIMS, Energy Dispersive X-ray Spectroscopy: EDX, or Electron Energy Loss Spectroscopy: EELS, can be used for qualitative and quantitative analysis of the chemical composition of the members constituting the semiconductor memory device herein.

In addition, for example, Transmission Electron Microscope: TEM can be used to measure the thickness, the distance between the members, and the like of the members constituting the semiconductor memory device.

In addition, for example, Transmission Electron Microscopy, X-ray Diffraction: XRD, Electron Beam Diffraction: EBD, X-ray Photoelectron Spectroscopy: XPS, or Synchrotron Radiation X-ray Absorption Fine Structure: XAFS can be used to identify the constituent materials of the members constituting the semiconductor memory device and comparison of large and small percentages of presence.

### First Embodiment

A semiconductor memory device of the present embodiment includes: a stacked body including a first insulating layer, a first conductive layer and a second insulating layer that are sequentially stacked in a first direction: a semiconductor film spaced apart from the stacked body, the semiconductor film extending in the first direction: a tunnel insulating film provided between the stacked body and the semiconductor film, the tunnel insulating film extending in the first direction: a first block insulating film provided between the first conductive layer and the tunnel insulating film: and a first charge storage film containing a metal oxide or a metal oxynitride, the first charge storage film including: a first portion provided between the tunnel insulating film and the first block insulating film, a second portion provided between the tunnel insulating film and the first insulating layer, the second portion being connected to the first portion and a third portion provided between the tunnel insulating film and the second insulating layer, the third portion being connected to the first portion.

A method of manufacturing the semiconductor device according to the present embodiment includes forming a stacked body including a first insulating layer, a first sacrifice layer and a second insulating layer that are sequentially stacked in a first direction: forming an opening penetrating through the stacked body in the first direction, and exposing a side surface of the first insulating layer, a side surface of the first sacrifice layer, and a side surface of the second insulating layer to the opening: forming a first film containing nitrogen or silicon on the side surface of the first sacrifice layer: forming a first charge storage film including a first portion, a second portion and a third portion, the first charge storage film containing a metal oxide or a metal oxynitride, the second portion being provided adjacent to the first insulating layer and the first film, the third portion being provided adjacent to the second insulating layer and the first film, the first film being provided between the first sacrifice layer and the first portion, and the first portion being connected to the second portion and the third portion: oxidizing the first film to form a first block insulating film: forming a tunnel insulating film extending in the first direction, the first block insulating film being provided between the stacked body and the tunnel insulating film: and forming a semiconductor film extending in the first direction, the tunnel insulating film being provided between the stacked body and the semiconductor film.

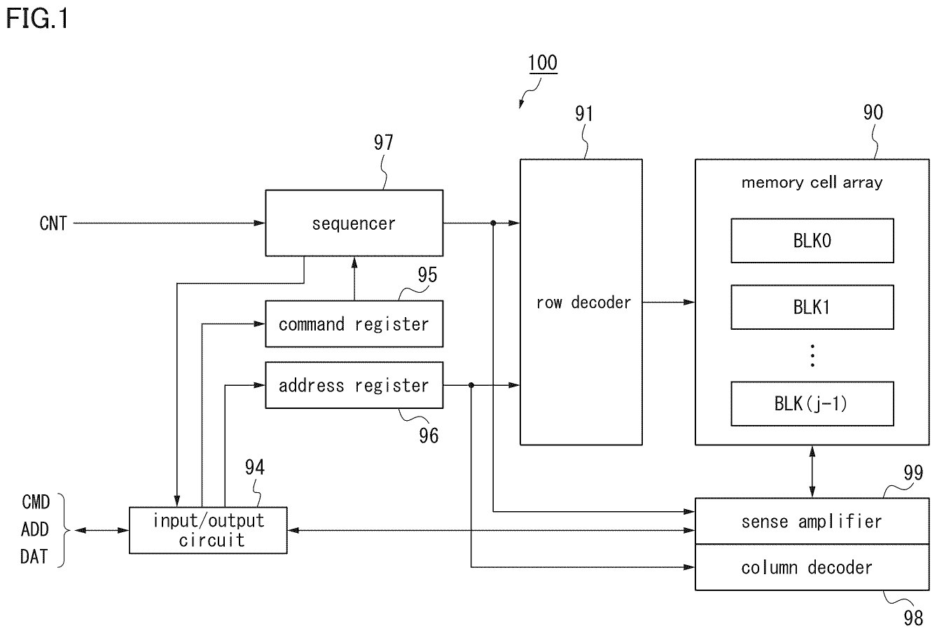

The entire configuration of the semiconductor memory device 100 will be described. The semiconductor memory device 100 according to the present embodiment is a NAND flash memory capable of storing data non-volatilely. FIG. 1 is the diagram of the semiconductor memory device 100 according to the present embodiment.

The semiconductor memory device 100 includes a memory cell array 90, a row decoder 91, a column decoder 98, a sense amplifier 99, an input/output circuit 94, a command register 95, an address register 96, and a sequencer (control circuitry) 97.

The memory cell array 90 includes j blocks BLK0-BLK(j−1). j is an integer of 1 or more. Each of the plurality of blocks BLK includes a plurality of memory cell transistors. The memory cell transistor includes an electrically rewritable memory cell. The memory cell array 90 includes a plurality of bit lines, a plurality of word lines, and a source line, etc. to control the voltage applied to the memory cell transistor. A specific configuration of the block BLK will be described later.

The row decoder 91 receives a row address from the address register 96 and decodes the row address. The row decoder 91 performs a selection operation of the word lines and so on based on the decoded row address. The row decoder 91 transmits a plurality of voltages required for a write operation, a read operation, and an erase operation to the memory cell array 90.

The column decoder 98 receives the column address from the address register 96 and decodes this column address. The column decoder 98 performs a selection operation of the bit lines based on the decoded column address.

During the read operation, the sense amplifier 99 detects and amplifies the data read from the memory cell transistor to the bit line. During the write operation, the sense amplifier 99 transfers the write data to the bit line.

The input/output circuit 94 is connected to an external device (host device) via a plurality of input/output lines (DQ lines). The input/output circuit 94 receives the command CMD and the address ADD from the external device. The command CMD received by the input/output circuit 94 is sent to the command register 95. The address ADD received by the input/output circuit 94 is sent to an address register 96. The input/output circuit 94 transmits and receives DAT to and from the external device.

The sequencer 97 receives a control signal CNT from the external device. The control signal CNT includes the chip enable signal CEn, the command latch enable signal CLE, the address latch enable signal ALE, the write enable signal WEn, and the read enable signal REn. The “n” appended to the signal name indicates active low. The sequencer 97 controls the operation of the entire semiconductor memory device 100 based on the command CMD and the control signal CNT held in the command register 95.

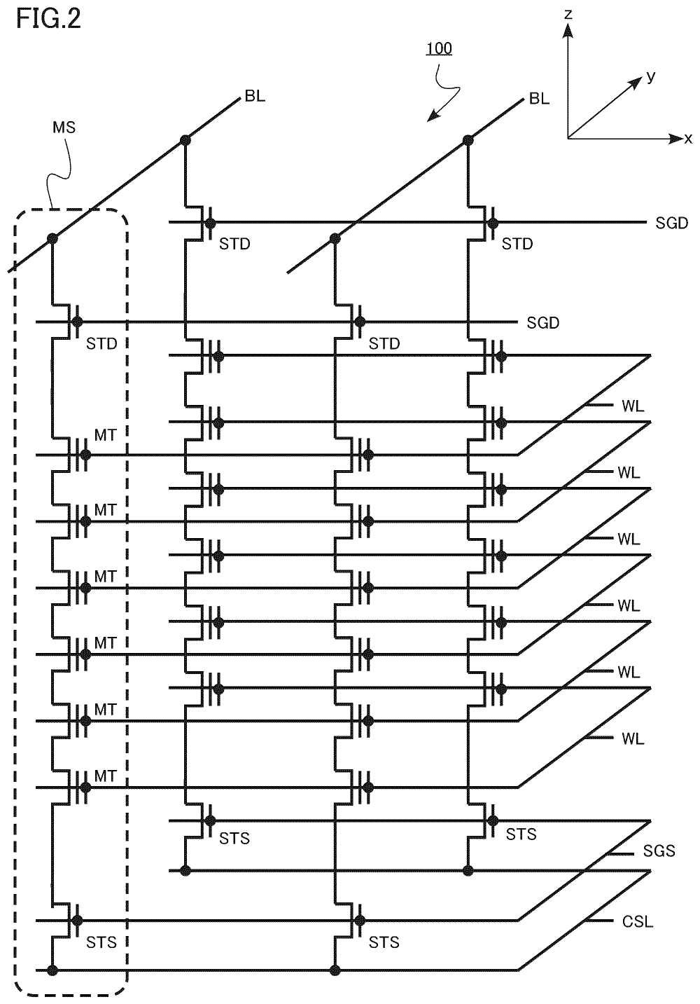

FIG. 2 is the equivalent circuit diagram of the semiconductor memory device 100 of the present embodiment.

As shown in FIG. 2, the semiconductor memory device 100 includes a plurality of word lines WL, a common source line CSL, a source selection gate line SGS, a plurality of drain select gate lines SGD, a plurality of bit lines BL, and a plurality of memory strings MS.

The memory string MS has a source selection transistor STS, a plurality of memory cell transistors MT, and a drain selection transistor STD connected in series between the common source line CSL and the bit line BL.

The number of word lines WL, the number of bit lines BL, the number of memory strings MS, and the number of drain select gate lines SGD are not limited to those of FIG. 2.

Here, X direction, Y direction that intersects perpendicularly with the X direction, and Z direction that intersects perpendicularly with the X direction and the Y direction are defined. The Z direction is an exemplary the first direction.

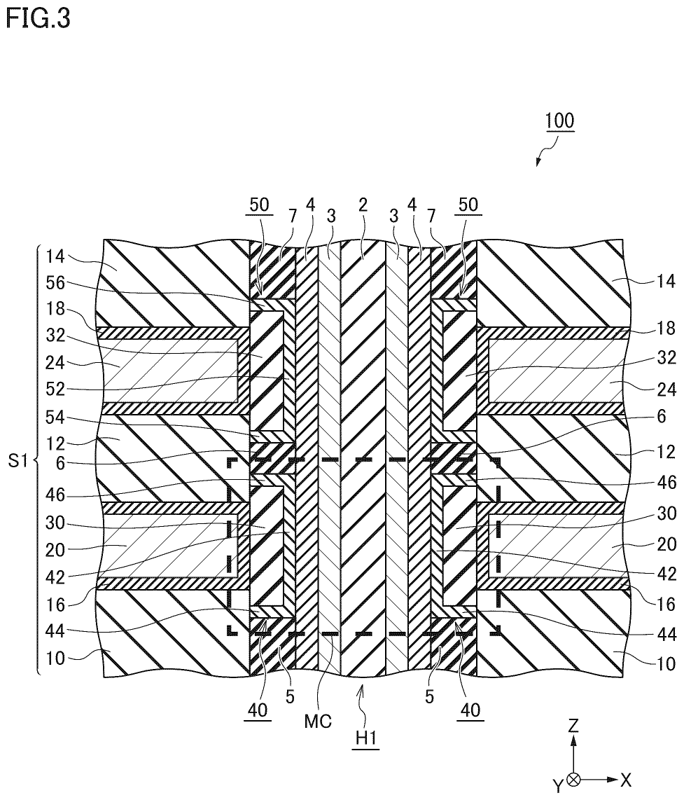

FIG. 3 is the schematic cross-sectional view of the main part of the semiconductor memory device 100 of the present embodiment.

The first insulating layer 10, the first conductive layer 20, the second insulating layer 12, the second conductive layer 24, and the third insulating layer 14 are sequentially stacked in the Z direction. That is, the insulating layer and the conductive layer are alternately stacked in the Z direction. Thus, the first stacked body S1 is provided. The first stacked body SI may further include other insulating layers and conductive layers. In this case, in the first stacked body S1, a plurality of insulating layers and a plurality of conductive layers are stacked one by one in the Z direction.

The first insulating layer 10, the second insulating layer 12, and the third insulating layer 14 include insulating materials. The first insulating layer 10, the second insulating layer 12, and the third insulating layer 14 include, for example, silicon oxide.

The first conductive layer 20 and the second conductive layer 24 include conductive materials. The first conductive layer 20 and the second conductive layer 24 include, for example, tungsten, titanium nitride, or copper. The first conductive layer 20 and the second conductive layer 24 may include a conductive material such as another metal, a metal semiconductor compound, or a semiconductor.

The memory pillar Hl penetrates the first stacked body S1 in the Z direction. In the memory pillar H1, the core-insulating film 2, the semiconductor film 3, the tunnel insulating film 4, the first insulating film 5, the second insulating film 6, the third insulating film 7, the first block insulating film 30, the second block insulating film 32, the first charge storage film 40, and the second charge storage film 50 are provided. The core-insulating film 2 extends in the Z direction. The core-insulating film 2 includes, for example, silicon oxide.

The semiconductor film 3 is provided around the core-insulating film 2 in the memory pillar H1. The semiconductor film 3 extends in the Z direction. The semiconductor film 3 functions as a channel of the memory pillar H1. The semiconductor film 3 includes, for example, a semiconductor material such as polysilicon.

The tunnel insulating film 4 is provided around the semiconductor film 3. The tunnel insulating film 4 is an insulating film that is insulating but allows a current to flow by applying a predetermined voltage. The tunnel insulating film 4 includes, for example, silicon oxynitride.

The first block insulating film 30 is provided between the first conductive layer 20 and the tunnel insulating film 4. A portion of the first block insulating film 30 is provided across between the first insulating layer 10 and the tunnel insulating film 4 and between the second insulating layer 12 and the tunnel insulating film 4. The first block insulating film 30 is a film that prevents electric charges from flowing between the first conductive layer 20 and the tunnel insulating film 4. The first block insulating film 30 includes, for example, an oxide or an oxynitride. The first block insulating film 30 includes, for example, a silicon oxide or a silicon oxynitride. The first block insulating film 30 is a film that prevents electric charges from flowing between the first charge storage film 40 and the first conductive layer 20.

The second block insulating film 32 is provided between the second conductive layer 24 and the tunnel insulating film 4. A portion of the second block insulating film 32 is provided between the second insulating layer 12 and the tunnel insulating film 4 and between the third insulating layer 14 and the tunnel insulating film 4. The second block insulating film 32 is a film that prevents electric charges from flowing between the second conductive layer 24 and the tunnel insulating film 4. The second block insulating film 32 includes, for example, an oxide or an oxynitride. The second block insulating film 32 includes, for example, a silicon oxide or a silicon oxynitride. The second block insulating film 32 is a film that prevents electric charges from flowing between the second charge storage film 50 and the second conductive layer 24.

The first charge storage film 40 includes the first portion 42, the second portion 44, and the third portion 46. The first portion 42 is provided between the tunnel insulating film 4 and the first block insulating film 30. The second portion 44 is provided between the tunnel insulating film 4 and the first insulating layer 10, and is connected to the first portion 42. The third portion 46 is provided between the tunnel insulating film 4 and the second insulating layer 12, and is connected to the first portion 42. The first charge storage film 40 is a film containing a material capable of storing electric charges.

The second charge storage film 50 includes the sixth portion 52, the seventh portion 54, and the eighth portion 56. The sixth portion 52 is provided between the tunnel insulating film 4 and the second block insulating film 32. The seventh portion 54 is provided between the tunnel insulating film 4 and the second insulating layer 12, and is connected to the sixth portion 52. The eighth portion 56 is provided between the tunnel insulating film 4 and the third insulating layer 14, and is connected to the sixth portion 52. The second charge storage film 50 is a film containing a material capable of storing electric charges.

The first charge storage film 40 and the second charge storage film 50 contain the metal oxide or the metal oxynitride. This is because the metal oxide or the metal oxynitride has a high-charge-retention property.

The first charge storage film 40 and the second charge storage film 50 preferably contain at least one first element selected from the group consisting of Al (aluminum), Hf (hafnium), Zr (zirconium), Ti (titanium), V (vanadium), Ta (tantalum), and Nb (niobium), and may be oxides or oxynitrides of these elements. For example, when the first element is Hf, the first charge storage film 40 and the second charge storage film 50 may be HfO or HfON, and for example, when the first element is Zr, the first charge storage film 40 and the second charge storage film 50 may be ZrO or ZrON.

Alternatively, the first charge storage film 40 and the second charge storage film 50 preferably contain at least one second element selected from the group consisting of N (nitrogen), Si (silicon), Al (aluminum), and lanthanoid elements, and Hf or Zr. The first charge storage film 40 and the second charge storage film 50 may be, for example, oxides or oxynitrides such as HfAlO, HfAlON, ZrAlO, or ZrAlON. Further, the first charge storage film 40 and the second charge storage film 50 preferably contain 20 atomic % or less of the second element.

The first insulating film 5 is provided between the tunnel insulating film 4 and the first insulating layer 10. The second insulating film 6 is provided between the tunnel insulating film 4 and the second insulating layer 12. The third insulating film 7 is provided between the tunnel insulating film 4 and the third insulating layer 14. In the Z direction, the second insulating film 6 is provided between the third portion 46 and the seventh portion 54. The first insulating film 5, the second insulating film 6, and the third insulating film 7 include an insulating material. The first insulating film 5, the second insulating film 6, and the third insulating film 7 include, for example, silicon oxide. The first insulating film 5, the second insulating film 6, and the third insulating film 7 are films embedded between the respective charge storage film in the Z direction.

The third block insulating film 16 is provided between the first conductive layer 20 and the first insulating layer 10, between the first conductive layer 20 and the first block insulating film 30, and between the first conductive layer 20 and the second insulating layer 12. The third block insulating film 16 includes, for example, a metallic insulating material such as aluminum oxide.

The fourth block insulating film 18 is provided between the second conductive layer 24 and the second insulating layer 12, between the second conductive layer 24 and the second block insulating film 32, and between the second conductive layer 24 and the third insulating layer 14. The fourth block insulating film 18 includes, for example, a metallic insulating material such as aluminum oxide.

A barrier metal (not shown) is provided between the first conductive layer 20 and the third block insulating film 16 and between the second conductive layer 24 and the fourth block insulating film 18. The barrier metal contains, for example, titanium nitride.

Note that in FIG. 3, one memory string MS of the memory strings MS shown in FIG. 2 is shown. The semiconductor memory device 100 includes a plurality of memory pillars H1.

In FIG. 3, a portion surrounded by a broken line is a portion corresponding to one memory cell MC.

A substrate (not shown) is provided below the first stacked body S1, for example. The substrate (not shown) is, for example, a semiconductor wafer or a SOI wafer. The common source line CSL (not shown), the source select gate line SGS (not shown), and a plurality of source selection transistors STS (not shown) are provided between the first stacked body S1 and the substrate (not shown).

On the first stacked body S1, for example, a plurality of drain select gate lines SGD, a plurality of bit lines BL, and a plurality of drain selection transistors STD (not shown) are provided.

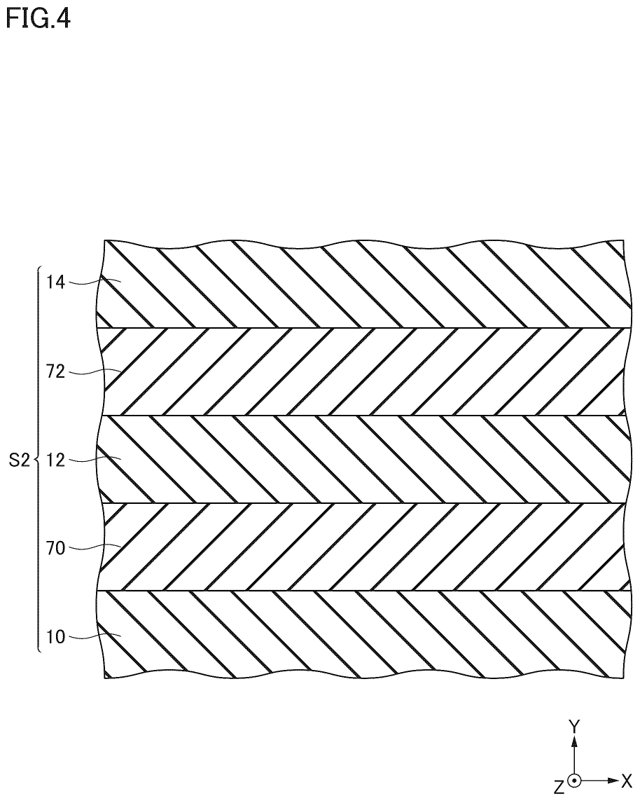

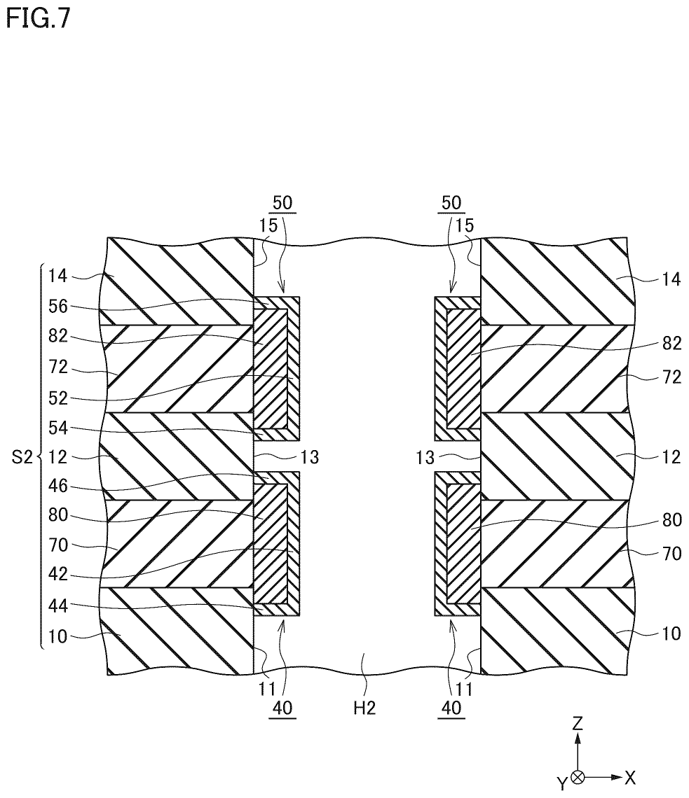

FIG. 4 to FIG. 9 are schematic cross-sectional views showing methods for manufacturing the semiconductor memory device of the present embodiment. First, for example, the common source line CSL (not shown), the source select gate line SGS (not shown), and the plurality of source selection transistors STS (not shown) are formed on the substrate (not shown).

Next, the second stacked body S2 is formed by, for example, plasma CVD (Plasma-enhanced Chemical Vapor Deposition) method, on the common source line CSL, the source select gate line SGS, and the plurality of source selection transistors STS (not shown), and in the second stacked body S2, the first insulating layer 10, the first sacrifice layer 70, the second insulating layer 12, the second sacrifice layer 72, and the third insulating layer 14 are sequentially stacked in the Z direction. Here, the first insulating layer 10, the second insulating layer 12, and the third insulating layer 14 include, for example, silicon oxide. The first sacrifice layer 70 and the second sacrifice layer 72 include, for example, silicon nitride (FIG. 4).

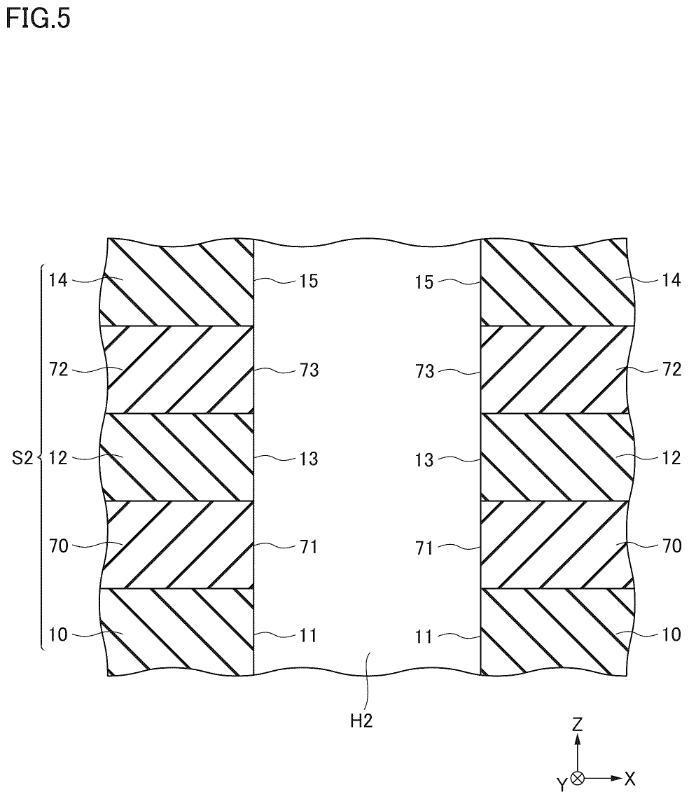

Next, for example, by RIE (Reactive Ion Etching) method, the opening H2 (through-hole) is formed which penetrates through the second stacked body S2 in the Z direction and extends in the Z direction. This exposes the side surface 11 of the first insulating layer, the side surface 71 of the first sacrifice layer, the side surface 13 of the second insulating layer, the side surface 73 of the second sacrifice layer, and the side surface 15 of the third insulating layer to the opening H2 (FIG. 5).

Next, the adsorption inhibitor I is adsorbed on the side surface 11 of the first insulating layer, the side surface 13 of the second insulating layer, and the side surface 15 of the third insulating layer. The adsorption inhibitor I is not particularly limited, and for example, C (carbon), a hydrocarbon, or the like can be used.

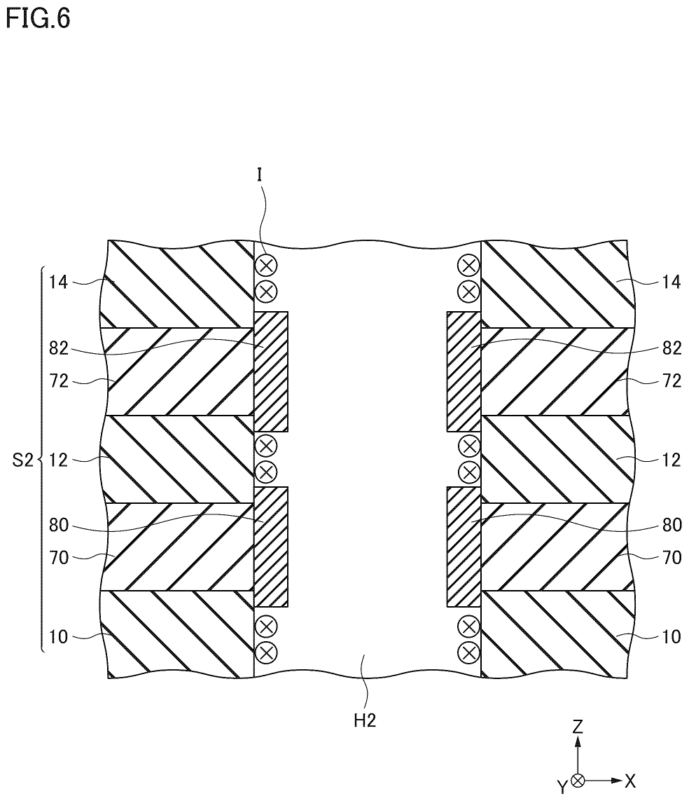

Next, the first film 80 containing N (nitrogen) or Si (silicon) is formed on the side surface 71 of the first sacrifice layer, for example, by the Area Selective Deposition (ASD). The second film 82 containing N (nitrogen) or Si (silicon) is formed on the side surface 73 of the second sacrifice layer, for example, by the Area Selective Deposition (ASD). For example, the first film 80 and the second film 82 including silicon nitride are formed by the selective CVD method. Here, a portion of the first film 80 may be formed adjacently to the side surface 11 of the first insulating layer and the side surface 13 of the second insulating layer. In addition, a portion of the second film 82 may be formed adjacently to the side surface 13 of the second insulating layer and the side surface 15 of the third insulating layer. The first film 80 and the second film 82 are formed to be spaced apart from each other (FIG. 6).

In the following figures, the adsorption inhibitor I is not shown.

Next, the first charge storage film 40 including the first portion 42, the second portion 44 and the third portion 46 and containing the metal oxide or the metal oxynitride is formed, by for example, the Area Selective Deposition. Here, the first charge storage film 40 is formed so that the second portion 44 is adjacent to the first insulating layer 10 and the first film 80, the third portion 46 is adjacent to the second insulating layer 12 and the first film 80, the first film 80 is provided between the first sacrifice layer 70 and the first portion 42, and the first portion 42 is connected to the second portion 44 and the third portion 46.

Further, the second charge storage film 50 including the sixth portion 52, the seventh portion 54, and the eighth portion 56 and containing the metal oxide or the metal oxynitride is formed by, for example, the Area Selective Deposition. Here, the second charge storage film 50 is formed so that the seventh portion 54 is adjacent to the second insulating layer 12 and the second film 82, the eighth portion 56 is adjacent to the third insulating layer 14 and the second film 82, the second film 82 is provided between the second sacrifice layer 72 and the sixth portion 52, and the sixth portion 52 is connected to the seventh portion 54 and the eighth portion 56.

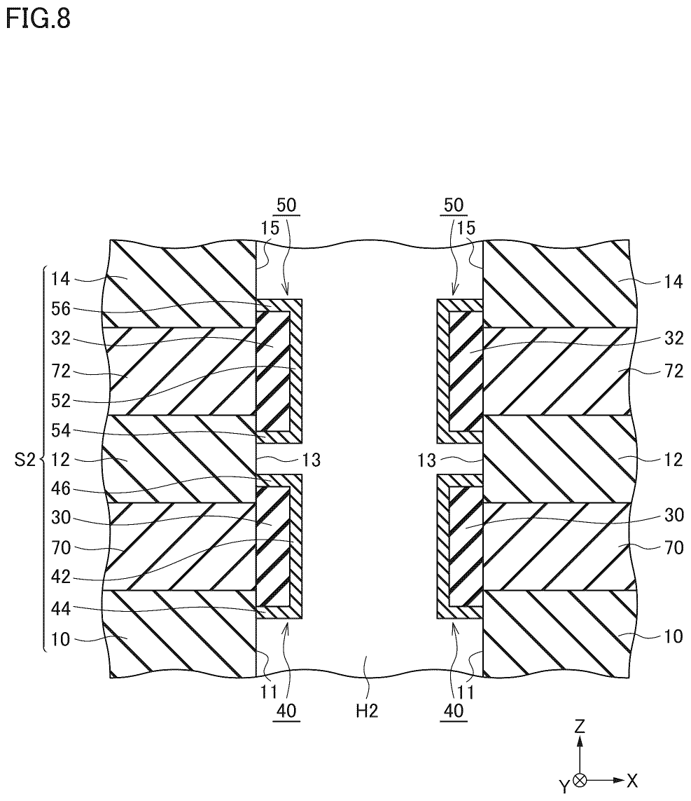

Next, the first film 80 is oxidized to form the first block insulating film 30. The second film 82 is also oxidized to form the second block insulating film 32. For example, the first block insulating film 30 is formed by supplying an oxygen-containing gas into the opening H2 and oxidizing the first film 80 via the first charge storage film 40 using the first charge storage film 40 as a catalyst. Further, the second block insulating film 32 is formed by supplying an oxygen-containing gas into the opening H2 and oxidizing the second film 82 via the second charge storage film 50 using the second charge storage film 50 as a catalyst (FIG. 8).

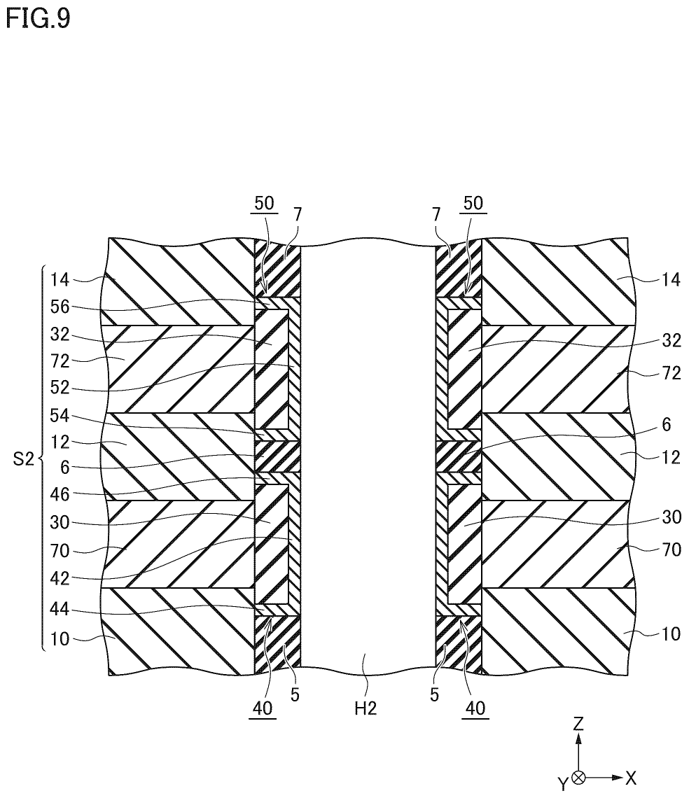

Next, a film including, for example, silicon oxide, is formed on the side surface 11 of the first insulating layer, the lower surface of the second portion 44, the side surface of the first portion 42, the side surface 13 of the second insulating layer, the side surface of the sixth portion 52, and the upper surface of the eighth portion 56. Next, a portion of the film containing silicon oxide is removed by, e.g., RIE so that the side surface of the first portion 42 and the side surface of the sixth portion 52 are exposed. Thus, the first insulating film 5 is formed on the side surface 11 of the first insulating layer. Further, the second insulating film 6 is formed on the side surface 13 of the second insulating layer. Further, the third insulating film 7 is formed on the side surface 15 of the third insulating layer (FIG. 9).

Next, in the opening H2, a portion of the tunnel insulating film 4 and a portion of the semiconductor film 3 are sequentially formed by, for example, the ALD method. A portion of the tunnel insulating film 4 and a portion of the semiconductor film 3 is then removed from the bottom of the opening H2, by, for example, the etching. Next, a rest of the semiconductor film 3 and the core-insulating film 2 are sequentially formed in the opening H2 by, for example, ALD. Accordingly, the tunnel insulating film 4, the semiconductor film 3, and the core-insulating film 2 are sequentially formed in the opening H2.

In other words, in the opening H2, the tunnel insulating film 4 extending in the first direction is formed so that the first block insulating film 30 and the second block insulating film 32 are provided between the second stacked body S2 and the tunnel insulating film 4. Next, in the opening H2, the semiconductor film 3 extending in the first direction is formed so that the tunnel insulating film 4 is provided between the second stacked body S2 and the semiconductor film 3. Next, the core-insulating film 2 extending in the first direction is formed in the opening H2 so that the semiconductor film 3 is provided between the second stacked body S2 and the core-insulating film 2.

Next, a slit (not shown) is formed in the second stacked body S2. Next, a chemical solution such as phosphoric acid is supplied using the slit, and the first sacrifice layer 70 and the second sacrifice layer 72 are removed. Next, the third block insulating film 16 and the first conductive layer 20 are sequentially formed on the portion where the first sacrifice layer 70 is removed. In addition, the fourth block insulating film 18 and the second conductive layer 24 are sequentially formed on the portion where the second sacrifice layer 72 is removed. In this way, the first sacrifice layer 70 is replaced with the third block insulating film 16 and the first conductive layer 20. The second sacrifice layer 72 is also replaced with the fourth block insulating film 18 and the second conductive layer 24. Thus, the first stacked body SI is formed.

Next, the plurality of drain select gate lines SGD, the plurality of the bit lines BL, and the plurality of drain selection transistors STD (not shown) are formed on the second stacked body S2. As a result, the semiconductor memory device 100 of the present embodiment is obtained.

Next, the operation and effects of semiconductor memory device of the present embodiment will be described.

In the first stacked body S1, the film thickness of the insulating layer in the Z direction and the film thickness of the conductive layer in the Z direction tend to be thinner due to high memory density of the semiconductor memory device. In this case, the spacing between neighboring memory cells MC in the Z direction is reduced. Therefore, the interference and the charge-transfer between neighboring memory cells MC in the Z direction may be the problems.

In order to solve the problems, it is conceivable to reduce the film thickness of the charge storage film in the X direction or the Y direction. However, when silicon nitride is used as the charge storage film, when the film thickness in the X direction or the Y direction is thinner than, for example, about 5 nm, the amount of the charge accumulation rapidly decreases.

Therefore, it is conceivable to use a film including the metal oxide or the metal oxynitride extending in the Z direction as the charge storage film. However, there is a problem that, in the Z direction, charge-transfer occurs between neighboring memory cells MC.

Therefore, the semiconductor memory device of the present embodiment includes: a first stacked body including a first insulating layer, a first conductive layer and a second insulating layer, and the first insulating layer, the first conductive layer and the second insulating layer being sequentially stacked in a first direction; a semiconductor film spaced apart from the first stacked body, and the semiconductor film extending in the first direction; a tunnel insulating film provided between the first stacked body and the semiconductor film, and the tunnel insulating film extending in the first direction: a first block insulating film provided between the first conductive layer and the tunnel insulating film; and a first charge storage film containing a metal oxide or a metal oxynitride, and the first charge storage film including a first portion provided between the tunnel insulating film and the first block insulating film, a second portion provided between the tunnel insulating film and the first insulating layer, and the second portion being connected to the first portion and a third portion provided between the tunnel insulating film and the second insulating layer, and the third portion being connected to the first portion.

According to the semiconductor memory device of the present embodiment, the charge storage film is divided between the memory cells MC. Therefore, the interference and the charge transfer between neighboring memory cells MC in the Z direction is suppressed. In addition, the semiconductor memory device of the present embodiment can ensure a higher capacitance. Therefore, the semiconductor memory device having high charge retention characteristics can be provided.

The first charge storage film 40 and the second the charge storage film 50 preferably contain at least one first element selected from the group consisting of Al (aluminum), Hf (hafnium), Zr (zirconium), Ti (titanium), V (vanadium), Ta (tantalum), and Nb (niobium). This is because the first charge storage film 40 and the second charge storage film 50 have high charge retention characteristics.

The first charge storage film 40 and the second charge storage film 50 preferably contain at least one second element selected from the group consisting of N (nitrogen), Si (silicon), Al (aluminum), and lanthanoid elements, and Hf or Zr. Further, the first charge storage film 40 and the second charge storage film 50 preferably contain 20 atomic % or less of the second element. This is because the first charge storage film 40 and the second charge storage film 50 have high charge retention characteristics.

In the manufacturing method of the semiconductor memory device of the present embodiment, the first film 80 is oxidized to form the first block insulating film 30. For example, the first film 80 is oxidized via the first charge storage film 40 using the first charge storage film 40 as catalyst to form the first block insulating film 30. This is because the memory cell MC in which the charge storage film is divided in the Z direction can be formed while the block insulating film is formed.

The adsorption inhibitor I is preferably adsorbed on the side surface 11 of the first insulating layer, the side surface 13 of the second insulating layer, and the side surface 15 of the third insulating layer. This is because it is possible to suppress the formation of a film including the metal oxide or the metal oxynitride on the side surface 11 of the first insulating layer, the side surface 13 of the second insulating layer, and the side surface 15 of the third insulating layer.

According to the semiconductor memory device of the present embodiment, it is possible to provide the semiconductor memory device having high charge retention characteristics.

### Second Embodiment

The semiconductor memory device of the present embodiment differs from the first conductive layer of the first embodiment in that the first conductive layer includes a fourth portion provided between the first insulating layer and the second insulating layer, and a fifth portion provided between the second portion and the third portion, the fifth portion being connected to the fourth portion, and a film thickness of the fifth portion in the first direction being thicker than a film thickness of the fourth portion in the first direction. Descriptions of the contents overlapping with those of the first embodiment will be omitted.

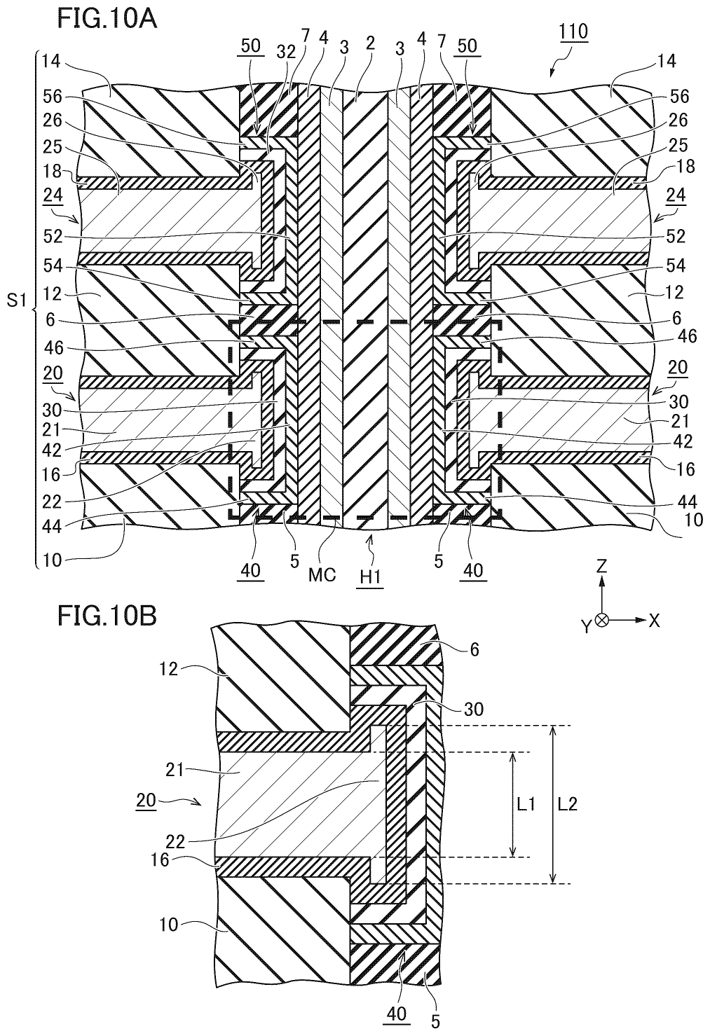

FIGS. 10A-B are the schematic cross-sectional views of the main part of the semiconductor memory device 110 of the present embodiment. FIG. 10A is the schematic cross-sectional view of the main part of the semiconductor memory device 110 of the present embodiment. FIG. 10B is the schematic cross-sectional view of the main part of the semiconductor memory device 110 of the present embodiment in the vicinity of the first conductive layer 20.

The first conductive layer 20 includes the fourth portion 21 provided between the first insulating layer 10 and the second insulating layer 12, and the fifth portion 22 provided between the second portion 44 and the third portion 46. The fifth portion 22 is connected to the fourth portion 21. The film thickness of the fifth portion 22 in the Z direction is thicker than the film thickness of the fourth portion 21 in the Z direction.

The second conductive layer 24 includes the ninth portion 25 provided between the second insulating layer 12 and the third insulating layer 14, and the tenth portion 26 provided between the seventh portion 54 and the eighth portion 56. The tenth portion 26 is connected to the ninth portion 25. The film thickness of the tenth portion 26 in the Z direction is thicker than the film thickness of the ninth portion 25 in the Z direction.

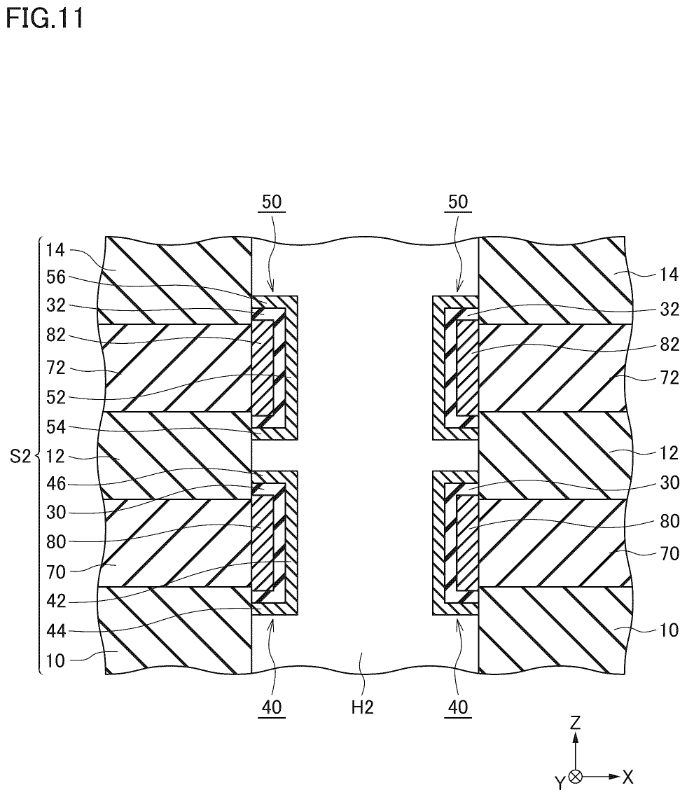

FIG. 11 is the schematic cross-sectional view showing the method for manufacturing the semiconductor memory device 110 of the present embodiment.

The manufacturing method until the first charge storage film 40 and the second the charge storage film 50 are formed is the same as the manufacturing method of the semiconductor memory device 100 of the first embodiment.

In the manufacturing method of the semiconductor memory device 110 of the present embodiment, when the first film 80 is oxidized to form the first block insulating film 30, a portion of the first film 80 remains between the first sacrifice layer 70 and the first block insulating film 30. In other words, when the first film 80 is oxidized to form the first block insulating film 30, the first film 80 is oxidized so that a portion of the first film 80 is provided between the first sacrifice layer 70 and the first block insulating film 30.

At this time, the length of the portion of the first film 80 in the Z direction is longer than the length of the first sacrifice layer 70 in the Z direction.

Similarly, when the second film 82 is oxidized to form the second block insulating film 32, a portion of the second film 82 remains between the second sacrifice layer 72 and the second block insulating film 32. In other words, when the second film 82 is oxidized to form the second block insulating film 32, the second film 82 is oxidized so that a portion of the second film 82 is provided between the second sacrifice layer 72 and the second block insulating film 32.

At this time, the length of the portion of the second film 82 in the Z direction is longer than the length of the second sacrifice layer 72 in the Z direction.

The first sacrifice layer 70 and the portion of the first film 80 is then replaced with the third block insulating film 16 and the first conductive layer 20. As a result, the first conductive layer 20 having the fourth portion 21 and the fifth portion 22 is formed.

Further, the second sacrifice layer 72 and the portion of the second film 82 is then replaced with the fourth block insulating film 18 and the second conductive layer 24. As a result, the second conductive layer 24 having the ninth portion 25 and the tenth portion 26 is formed.

The subsequent manufacturing methods are the same as those of the semiconductor memory device of the first embodiment.

When the first film 80 is oxidized to form the first block insulating film 30, a portion of the first sacrifice layer 70 may be oxidized. In particular, a portion of the upper surface and the lower surface of the first sacrifice layer 70 in contact with the first block insulating film 30 may be oxidized. Then, when the first sacrifice layer 70 is replaced with the third block insulating film 16 and the first conductive layer 20, in the X direction or the Y direction, the length of the portion of the first conductive layer 20 in the Z direction facing the first portion 42 becomes shorter. Therefore, it is difficult to secure a higher capacitance between the first portion 42 and the first conductive layer 20.

Therefore, the semiconductor memory device of the present embodiment includes the first conductive layer 20 including a fourth portion 21 provided between the first insulating layer 10 and the second insulating layer 12, and a fifth portion 22 provided between the second portion 44 and the third portion 36, the fifth portion 22 being connected to the fourth portion 21, and a film thickness of the fifth portion 22 in the Z direction being thicker than a film thickness of the fourth portion 21 in the Z direction.

This ensures a higher capacitance between the first portion 42 and the fifth portion 22.

Further, consider thinning the film thickness of the plurality of insulating layers and the plurality of conductive layers in the first stacked body S1. In this case, when the sacrifice layer is removed to replace the conductive layer with the sacrifice layer in the manufacturing process, there is a possibility that strength cannot be secured because the insulating layers are thin. By providing a portion of the first film 80 between the first sacrifice layer 70 and the first block insulating film 30, strength can be ensured in the manufacturing process.

According to the semiconductor memory device of the present embodiment, it is possible to provide the semiconductor memory device having high charge retention characteristics.

While certain embodiments and examples have been described, these embodiments and examples have been presented by way of example only, and are not intended to limit the scope of the inventions. Indeed, the novel embodiments described herein may be embodied in a wide variety of other forms: furthermore, various omissions, substitutions and changes in the form of the embodiments described herein may be made without departing from the spirit of the inventions. These embodiments and variations thereof fall within the scope and spirit of the invention, and fall within the scope of the invention described in the claims and equivalents thereof.

While certain embodiments have been described, these embodiments have been presented by way of example only, and are not intended to limit the scope of the inventions. Indeed, the semiconductor memory device and described herein may be embodied in a variety of other forms: furthermore, various omissions, substitutions and changes in the form of the devices and methods described herein may be made without departing from the spirit of the inventions. for manufacturing the same The accompanying claims and their equivalents are intended to cover such forms or modifications as would fall within the scope and spirit of the inventions.

What is claimed is:

1. A semiconductor memory device comprising:
a stacked body including a first insulating layer, a first conductive layer and a second insulating layer that are sequentially stacked in a first direction:
a semiconductor film spaced apart from the stacked body, the semiconductor film extending in the first direction:
a tunnel insulating film provided between the stacked body and the semiconductor film, the tunnel insulating film extending in the first direction:
a first block insulating film provided between the first conductive layer and the tunnel insulating film: and
a first charge storage film containing a metal oxide or a metal oxynitride, the first charge storage film including:
a first portion provided between the tunnel insulating film and the first block insulating film,
a second portion provided between the tunnel insulating film and the first insulating layer, the second portion being connected to the first portion and
a third portion provided between the tunnel insulating film and the second insulating layer, the third portion being connected to the first portion.

2. The semiconductor memory device according to claim 1, wherein the first charge storage film contains at least one first element selected from the group consisting of Al (aluminum), Hf (hafnium), Zr (zirconium), Ti (titanium), V (vanadium), Ta (tantalum) and Nb (niobium).

3. The semiconductor memory device according to claim 1, wherein
the first charge storage film contains
at least one second element selected from the group consisting of N (nitrogen), Si (silicon), Al (aluminum) and lanthanoid elements, and
Hf or Zr.

4. The semiconductor memory device according to claim 3, wherein
the first charge storage film contains 20 atomic % or less of the second element.

5. The semiconductor memory device according to claim 1, wherein
the first conductive layer includes:
a fourth portion provided between the first insulating layer and the second insulating layer, and
a fifth portion provided between the second portion and the third portion, the fifth portion being connected to the fourth portion, and a film thickness of the fifth portion in the first direction being thicker than a film thickness of the fourth portion in the first direction.

6. The semiconductor memory device according to claim 1, wherein
the stacked body further includes a second conductive layer and a third insulating layer that are sequentially stacked on the second insulating layer in the first direction, and the semiconductor memory device further comprising:
a second block insulating film provided between the second conductive layer and the tunnel insulating film, the second block insulating film being spaced apart from the first block insulating film:
a second charge storage film containing a metal oxide or a metal oxynitride, the second charge storage film being spaced from the first charge storage film, the second charge storage film including:
a sixth portion provided between the tunnel insulating film and the second block insulating film,
a seventh portion provided between the tunnel insulating film and the second insulating layer, the seventh portion being connected to the sixth portion, and
an eighth portion provided between the tunnel insulating film and the third insulating layer, the eighth portion being connected to the sixth portion.

7. The semiconductor memory device according to claim 1, further comprising:
a third block insulating film provided between the first conductive layer and the first insulating layer, the second insulating layer, and the first block insulating film.

8. A method of manufacturing a semiconductor device, comprising:
forming a stacked body including a first insulating layer, a first sacrifice layer and a second insulating layer that are sequentially stacked in a first direction:
forming an opening penetrating through the stacked body in the first direction, and exposing a side surface of the first insulating layer, a side surface of the first sacrifice layer, and a side surface of the second insulating layer to the opening:
forming a first film containing nitrogen or silicon on the side surface of the first sacrifice layer:
forming a first charge storage film including a first portion, a second portion and a third portion, the first charge storage film containing a metal oxide or a metal oxynitride, the second portion being provided adjacent to the first insulating layer and the first film, the third portion being provided adjacent to the second insulating layer and the first film, the first film being provided between the first sacrifice layer and the first portion, and the first portion being connected to the second portion and the third portion:
oxidizing the first film to form a first block insulating film:
forming a tunnel insulating film extending in the first direction, the first block insulating film being provided between the stacked body and the tunnel insulating film; and
forming a semiconductor film extending in the first direction, the tunnel insulating film being provided between the stacked body and the semiconductor film.

9. The method of manufacturing the semiconductor device according to claim 8, further comprising:
after oxidizing the first film, replacing the first sacrifice layer with a first conductive layer.

10. The method of manufacturing the semiconductor device according to claim 9, further comprising:
after oxidizing the first film and before replacing the first sacrifice layer with the first conductive layer, forming a third block insulating film provided between the first conductive layer and the first insulating layer, the second insulating layer and the first block insulating layer.

11. The method of manufacturing the semiconductor device according to claim 8, wherein a portion of the first film remains between the first sacrifice layer and the first block insulating film after oxidizing the first film.

12. The method of manufacturing the semiconductor device according to claim 11, wherein a length of the portion of the first film in the first direction is longer than a length of the first sacrifice layer in the first direction.

13. The method of manufacturing the semiconductor device according to claim 11, further comprising:
after oxidizing the first film, replacing the first sacrifice layer and the portion of the first film with the first conductive layer.

14. The method of manufacturing the semiconductor device according to claim 13, wherein the first conductive layer includes:
a fourth portion provided between the first insulating layer and the second insulating layer, and
a fifth portion provided between the second portion and the third portion, the fifth portion being connected to the fourth portion, and a film thickness of the fifth portion in the first direction being thicker than a film thickness of the fourth portion in the first direction.

15. The method of manufacturing the semiconductor device according to claim 8, further comprising:
after forming the opening and
before forming the first film on the side surface of the first sacrifice layer,
adsorbing an adsorption inhibitor on the side surface of the first insulating layer and the side surface of the second insulating layer.

16. The method of manufacturing the semiconductor device according to claim 8, wherein the first charge storage film contains at least one first element selected from the group consisting of Al (aluminum), Hf (hafnium), Zr (zirconium), Ti (titanium), V (vanadium), Ta (tantalum) and Nb (niobium).

17. The method of manufacturing the semiconductor device according to claim 8, wherein the first charge storage film contains
at least one second element selected from the group consisting of N (nitrogen), Si (silicon), Al (aluminum) and lanthanoid elements, and
Hf or Zr.

18. The semiconductor memory device according to claim 17, wherein
the first charge storage film contains 20 atomic % or less of the second element.
